(19) United States
(12) Patent Application Publication
(10) Pub. No.: US 2026/0190653 A1
(43) Pub. Date: Jul. 2, 2026

(54) DISPLAY PANEL, ELECTRONIC DEVICE, AND METHOD FOR MANUFACTURING DISPLAY PANEL

(71) Applicant: Samsung Display Co., Ltd., Yongin-Si (KR)

(72) Inventors: YANG-HO JUNG, Yongin-si (KR); YEONGWOO KWON, Yongin-si (KR); SIKWANG KIM, Yongin-si (KR); JIN-SU BYUN, Yongin-si (KR); DONGKYUN SEO, Yongin-si (KR); GWANGMIN CHA, Yongin-si (KR)

(21) Appl. No.: 19/362,479

(22) Filed: Oct. 20, 2025

(30) Foreign Application Priority Data
Dec. 30, 2024 (KR) 10-2024-0200953

(51) Int. Cl. H10K 59/123; H10K 59/12

(52) U.S. Cl. CPC H10K 59/123; H10K 59/1201

(57) ABSTRACT

A display panel of the present disclosure includes a first base layer in which an opening is defined. A pad electrode is disposed above the opening. A base insulating layer is disposed on the first base layer and a portion of the pad electrode, and a first contact hole is defined therein. A second base layer is disposed on the base insulating layer, and a second contact hole is defined therein. A protection layer is disposed on the second base layer, and a third contact hole is defined therein. The first contact hole is below the second contact hole, which is below the third contact hole. A connection electrode is disposed on the protection layer and is electrically connected to the pad electrode through the first to third contact holes. The third contact hole has a width greater than a width of the second contact hole.

This application claims priority to Korean Patent Application No. 10-2024-0200953, filed on Dec. 30, 2024, and all the benefits accruing therefrom under 35 U.S.C. § 119, the content of which in its entirety is herein incorporated by reference.

### BACKGROUND

### 1. Field

The present disclosure relates to a display panel, an electronic device, and a method for manufacturing a display panel, and more particularly, to a display panel, an electronic device, and a method for manufacturing a display panel with enhanced reliability.

### 2. Description of the Related Art

Electronic devices such as smartphones, tablets, laptop computers, automotive navigation systems, and smart televisions are being developed. These electronic devices are equipped with display devices for providing information.

Also being developed are various types of display devices for enhancing user experience (UX) and user interface (UI). These display devices are introduced with an increasingly wider display area and narrower non-display area.

### SUMMARY

The present disclosure aims to provide a display panel, an electronic device, and a method for manufacturing a display panel that is fabricated using a simplified manufacturing process while achieving improved display quality.

A display panel according to an embodiment of the present disclosure may include: a first base layer in which an opening is defined; a pad electrode above the opening; a base insulating layer disposed on the first base layer and a portion of the pad electrode. A first contact hole is defined in the base insulating layer. A second base layer is disposed on the base insulating layer. A second contact hole above the first contact hole is defined in the second base layer. A protection layer is disposed on the second base layer. A third contact hole above the first and second contact holes is defined in the protection layer. A connection electrode is disposed on the protection layer and electrically connected to the pad electrode through the first, second, and third contact holes.

According to an embodiment, a width of the third contact hole may be greater than a width of the second contact hole, and the width of the second contact hole may be greater than a width of the first contact hole.

According to an embodiment, the pad electrode may extend parallel to a plane defined by a first direction and a second direction intersecting the first direction.

According to an embodiment, the pad electrode may include: a first portion being in contact with the connection electrode; and a second portion not being in contact with the connection electrode. The first portion may be below the first contact hole in a planar view. The second portion may be disposed below the base insulating layer, and an upper surface of the second portion may be in direct contact with the base insulating layer. The base insulating layer may be in direct contact with a side surface of the second portion and may cover the second portion.

According to an embodiment, a lower surface of the connection electrode may be in direct contact with the protection layer, the second base layer, the base insulating layer, and the pad electrode.

According to an embodiment, the base insulating layer may include an amorphous silicon layer and a silicon oxide layer disposed on the amorphous silicon layer. The silicon oxide layer may have a thickness of 100 Å or greater.

According to an embodiment, the base insulating layer may include at least one of silicon oxide (SiOx), silicon nitride (SiNx), and silicon oxynitride (SiON). The second base layer may include an organic material. The protection layer may include at least one inorganic layer. A thickness of the second base layer may be greater than a thickness of the protection layer. The first base layer may include a display area and a non-display area, and the pad electrode may overlap the non-display area.

A method for manufacturing a display panel according to an embodiment may include: forming a pad electrode; forming a preliminary base insulating layer; forming a second preliminary base layer; forming a preliminary protection layer; forming an intermediate protection layer; forming a second intermediate base layer and a second intermediate base insulating layer; forming a protection layer, a second base layer, and a base insulating layer; and forming a connection electrode.

In the step of forming a pad electrode, the pad electrode may be formed on a first preliminary base layer. In the step of forming a preliminary base insulating layer, the preliminary base insulating layer may be formed on the first preliminary base layer and a portion of the pad electrode. In the step of forming a second preliminary base layer, the second preliminary base layer may be formed on the preliminary base insulating layer. In the step of forming a preliminary protection layer, the preliminary protection layer may be formed on the second preliminary base layer. In the step of forming an intermediate protection layer, the preliminary protection layer may be etched to form the intermediate protection layer. A third preliminary contact hole may be defined in the intermediate protection layer.

In the step of forming a second intermediate base layer and a second intermediate base insulating layer, the second preliminary base layer and the preliminary base insulating layer may be etched to form the second intermediate base layer and the intermediate base insulating layer. A second preliminary contact hole may be defined in the second intermediate base layer, and a first preliminary contact hole may be defined in the intermediate base insulating layer. In the step of forming a protection layer, a second base layer, and a base insulating layer, the intermediate protection layer, the second intermediate base layer, and the intermediate base insulating layer may be etched to form the protection layer, the second base layer, and the base insulating layer. A first contact hole may be defined in the protection layer, a second contact hole may be defined in the second base layer, and a third contact hole may be defined in the base insulating layer. In a planar view, the first contact hole may be below the second contact hole, and the second contact hole may be below the third contact hole.

In the step of forming a connection electrode, the connection electrode may be formed on the portion of the pad electrode, the protection layer, the second base layer, and the base insulating layer. The connection electrode may be electrically connected to the pad electrode through the first, second, and third contact holes. The third contact hole may have a width greater than a width of the second contact hole.

The method according to an embodiment may further include forming a hard mask on the intermediate protection layer and before the step of forming a second intermediate base layer and an intermediate base insulating layer.

The method according to an embodiment may further include removing the hard mask, after the step of forming a second intermediate base layer and an intermediate base insulating layer and before the step of forming a protection layer, a second base layer, and a base insulating layer.

An electronic device according to an embodiment of the present disclosure may include: a housing; an electronic module disposed inside the housing; and a display device disposed to overlap the electronic module. The display device may include: a display panel configured for displaying images; and a circuit board coupled to the display panel. The display panel may include: a first base layer having an opening defined therein; a pad electrode above the opening; a base insulating layer disposed on the first base layer and a portion of the pad electrode. A first contact hole is defined in the base insulating layer. A second base layer is disposed on the base insulating layer. A second contact hole above the first contact hole is defined in the second base layer. A protection layer is disposed on the second base layer. A third contact hole above the first and second contact holes is defined in the protection layer. A connection electrode is disposed on the protection layer and electrically connected to the pad electrode through the first, second, and third contact holes.

A width of the third contact hole may be greater than a width of the second contact hole. According to an embodiment, the electronic device may further include a metal pattern configured to electrically connect the display panel with the circuit board. According to an embodiment, the circuit board may include: a base film; and a bump electrode disposed between the base film and the base insulating layer. The bump electrode and the pad electrode may be electrically connected through the metal pattern.

The display panel according to the present disclosure may include a protection layer having at least one inorganic layer disposed on a second base layer that includes an organic material. As a result, outgas generated during the etching of the second base layer may be less likely to be released externally, thereby improving the display quality of the display device.

Moreover, since no insulating layers or conductive layers are disposed between the base layer and the protection layer, the connection electrode may be directly positioned on the side surface of the contact hole. This configuration may prevent the connection electrode from being severed by the insulating layers or conductive layers and may also prevent connection failures between the connection electrode and the pad electrode caused by residual material from the insulating layers or conductive layers. As a result, it is possible to provide a display device with enhanced reliability.

### BRIEF DESCRIPTION OF THE DRAWINGS

These and/or other features will become apparent and more readily appreciated from the following description of the embodiments, taken in conjunction with the accompanying drawings.

FIG. 1 is a perspective view of an electronic device according to an embodiment of the present disclosure.

FIG. 2 is an exploded perspective view of the electronic device according to an embodiment of the present disclosure.

FIG. 3 is a cross-sectional view of a display device taken along the I-I′ line of FIG. 2.

FIG. 4 is a simplified cross-sectional view of a display module according to an embodiment of the present disclosure.

FIG. 5 is a plan view of a display panel according to an embodiment of the present disclosure.

FIG. 6 is a cross-sectional view of a display module according to an embodiment of the present disclosure.

FIG. 7 is a plan view of a display panel according to an embodiment of the present disclosure.

FIG. 8 is an enlarged view of a portion of the display device according to an embodiment of the present disclosure.

FIG. 9A is a cross-sectional view of a portion of the display device taken along the II-II′ line of FIG. 8.

FIG. 9B is an enlarged view of the AA′ region shown in FIG. 9A.

FIGS. 10 and 11 are enlarged views of a portion of the display device according to an embodiment of the present disclosure.

FIG. 12 is a flow diagram illustrating a method for manufacturing a display device according to an embodiment of the present disclosure.

FIGS. 13A, 13B, 14A, 14B, 15, 16A, 16B, 17, 18A, 18B, 19, 20, 21A, 21B, 22A, 22B, 23A, 23B, 24, 25, and 26 are schematic diagrams illustrating respective steps of the method for manufacturing a display device according to an embodiment of the present disclosure.

FIGS. 27 and 28 are views illustrating electronic devices incorporating the display device according to embodiments of the present disclosure.

### DETAILED DESCRIPTION

The inventive concept now will be described more fully hereinafter with reference to the accompanying drawings, in which various embodiments are shown. The inventive concept may, however, be embodied in many different forms, and should not be construed as limited to the embodiments set forth herein. Rather, these embodiments are provided so that this disclosure will be thorough and complete, and will fully convey the scope of the inventive concept to those skilled in the art.

When an element (or region, layer, portion, etc.) is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. On the other hand, if one element is described to be “directly disposed on,” “directly placed on,” “directly arranged on,” “directly connected to,” or “directly coupled to” another element, it shall be construed that there is no other element interposed therebetween.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, etc. illustrated in the drawings.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein. Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the present specification, when a particular process sequence may be implemented differently, the described sequence of processes may be performed in a different order. For example, two sequentially described processes may be performed substantially simultaneously, or the order of description may be reversed.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

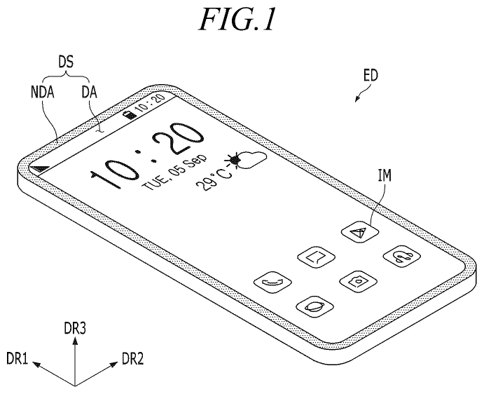

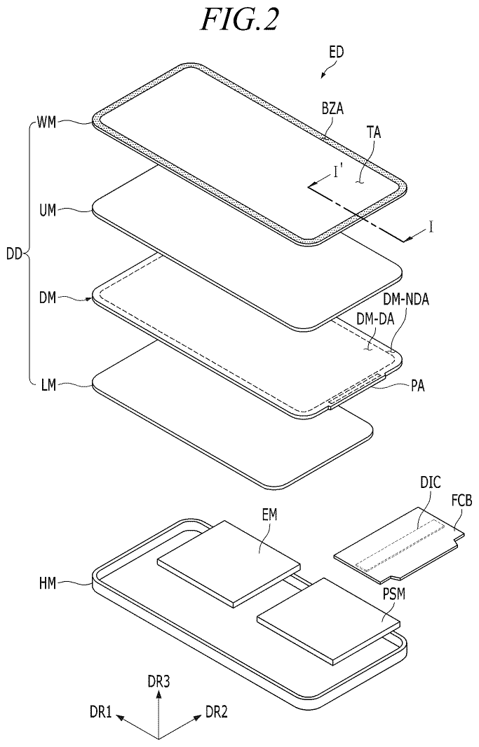

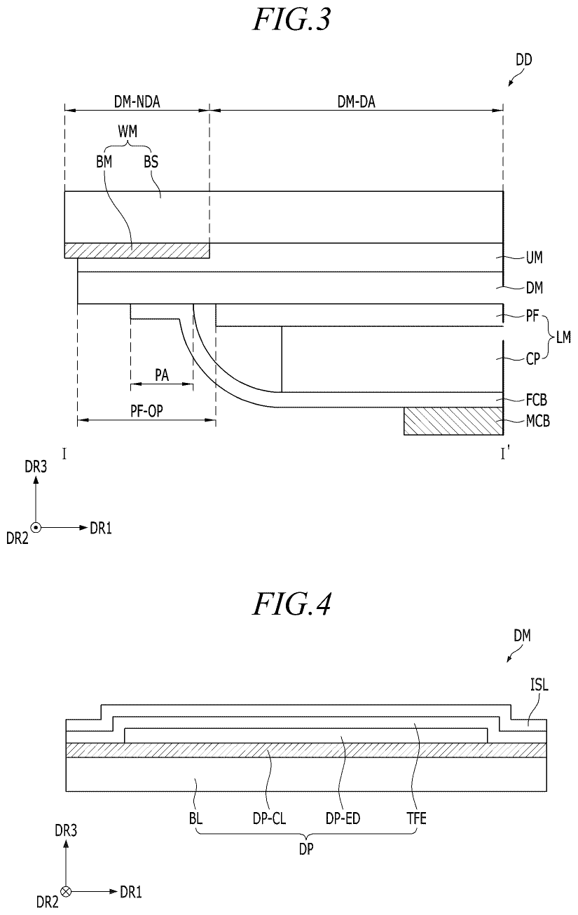

FIG. 1 illustrates a perspective view of an electronic device ED according to an embodiment of the disclosure. FIG. 2 illustrates an exploded perspective view of the electronic device ED according to an embodiment of the disclosure. FIG. 3 illustrates a cross-sectional view of a display device DD taken along the I-I′ line of FIG. 2.

Referring to FIG. 1, the electronic device ED according to an embodiment of the disclosure may include a display surface DS that is defined by a first direction DR1 and a second direction DR2, which intersects the first direction DR1. The electronic device ED may be configured to provide an image IM to a user through the display surface DS.

The display surface DS may include an outer display area DA and an outer non-display area NDA surrounding the outer display area DA. The outer display area DA may be an area in which the image IM is displayed, whereas the outer non-display area NDA may be an area where the image IM is not displayed. The outer non-display area NDA may enclose the outer display area DA. However, the shape of the outer display area DA and the outer non-display area NDA is not limited to what is described herein and may be subject to variation.

Hereinafter, a third direction DR3 may be defined as a direction that intersects substantially perpendicularly with the plane defined by the first direction DR1 and the second direction DR2. The third direction DR3 serves as a reference for distinguishing the front and rear surfaces of each component. In the present specification, “in a planar view” may refer to a state in which the display device DD is viewed from the third direction DR3.

In an embodiment of the present disclosure, the electronic device ED may be a foldable electronic device configured to fold about a folding axis. The folding axis may be parallel to the first direction DR1 or the second direction DR2, and a folding area may be defined in a portion of the outer display area DA. The electronic device ED may be configured to fold in to allow the outer display area DA to face toward each other or to fold out to allow the outer display area DA to face away from each other.

As illustrated in FIG. 2, the electronic device ED may include the display device DD, an electronic module EM, a power supply module PSM, and a housing HM. FIG. 2 illustrates a simplified view of the electronic device ED, but the electronic device ED may further include a mechanical structure, such as a hinge, configured to control the operation of the display device DD, such as folding or rolling.

The display device DD may be configured to generate the image IM and detect external input. The display device DD may include a window WM, an upper member UM, a display module DM, a lower member LM, a circuit board FCB, and a driving chip DIC. The upper member UM may include components disposed on the upper side of the display module DM, while the lower member LM may include components disposed on the lower side of the display module DM.

The window WM may provide the front surface of the electronic device ED. The window WM may include a transmissive area TA and a bezel area BZA. The outer display area DA and the outer non-display area NDA of the display surface DS shown in FIG. 1 may be defined by the transmissive area TA and the bezel area BZA. The transmissive area TA may correspond to an area through which an image is transmitted, while the bezel area BZA may correspond to an area covering structures or components disposed under the window WM.

The display module DM may include a display area DM-DA and a non-display area DM-NDA, corresponding to the outer display area DA and the outer non-display area NDA shown in FIG. 1, respectively. In the present specification, the term “corresponding” between areas or portions means that the areas or portions overlap but is not necessarily limited to mean an identical surface area.

A pad area PA may be defined on one side of the non-display area DM-NDA. The pad area PA may be an area electrically bonded or connected to the circuit board FCB described later. In an embodiment of the disclosure, the pad area PA may be an area defined on the rear surface of the display module DM.

The display module DM may have a substantially rectangular shape. The term “substantially rectangular shape” encompasses not only a mathematically defined rectangle but also any shape that may be perceived as rectangular by a user. For example, a substantially rectangular shape may include a rectangle having rounded corner regions. Additionally, a substantially rectangular display module DM may not necessarily have straight edges but may have a curved edge.

The upper member UM may include a protective film or an optical film. The optical film may include a polarizer and a retarder configured for reducing the reflection of external light. The lower member LM may include a protective film configured to protect the display module DM, a supporting member configured to support the display module DM, or a digitizer. Further details regarding the upper member UM and the lower member LM will be described later.

The circuit board FCB may be disposed below the display module DM. The circuit board FCB may be bonded to the rear surface of the display panel DP shown in FIG. 4. The circuit board FCB may be configured to electrically connect the display panel DP shown in FIG. 4 with a main circuit board MCB shown in FIG. 3. The circuit board FCB may include at least one insulating layer and at least one conductive layer. The conductive layer may include multiple signal lines.

The driving chip DIC may be mounted on the circuit board FCB. The driving chip DIC may include a driving circuit, such as for example a data driving circuit, configured for driving pixels of the display panel DP shown in FIG. 4. Although FIG. 2 illustrates a structure in which the driving chip DIC is mounted on the circuit board FCB, the disclosure is not limited to the illustrated configuration. For example, the driving chip DIC may be mounted on the display module DM or the main circuit board.

The electronic module EM may include a control module, a wireless communication module, an image input module, an audio input module, an audio output module, a memory, and an external interface module. The electronic module EM may include the main circuit board, and the above-described modules may be mounted on the main circuit board or electrically connected to the main circuit board via a flexible circuit board. The electronic module EM may be electrically connected to the power supply module PSM.

Although not explicitly illustrated, the electronic device ED may further include an optoelectronic module. The optoelectronic module may be an electronic component configured to output or receive an optical signal. The optoelectronic module may include a camera module and/or a proximity sensor. The camera module may be configured to capture an external image through a portion of the display panel DP.

The housing HM shown in FIG. 2 may be configured to accommodate the display device DD and other modules, particularly by being coupled with the window WM. The housing HM is illustrated as having an integrated shape, but the shape of the housing HM in the present disclosure is not limited to what is illustrated herein. The housing HM may rather include multiple parts, such as a side frame portion and a bottom portion, that are coupled with each other.

Referring to FIG. 3, the window WM may include a base substrate BS and a bezel pattern BM disposed on a lower surface of the base substrate BS. The base substrate BS may include a synthetic resin film or a glass substrate. The base substrate BS may have a multilayer structure. The base substrate BS may include a thin-film glass substrate, a protective film disposed on the thin-film glass substrate, and an adhesive layer bonding the thin-film glass substrate and the protective film.

The bezel pattern BM may be a colored light-blocking layer that is formed, for example, by a coating technique. The bezel pattern BM may include a base material and a dye or pigment mixed in the base material. The bezel pattern BM may overlap the outer non-display area NDA shown in FIG. 1 and the bezel area BZA shown in FIG. 2. The bezel pattern BM may be disposed on the lower surface of the base substrate BS. In the case where the base substrate BS has a multilayer structure, the bezel pattern BM may be disposed between interfaces defined by multiple layers. For example, the bezel pattern BM may be disposed between the thin-film glass substrate and the protective film. Although not explicitly illustrated, the window WM may further include at least one of a hard coating layer, a fingerprint-resistant layer, or an anti-reflective layer disposed on the base substrate BS.

The upper member UM may include an upper film. The upper film may include a synthetic resin film, which may include polyimide, polycarbonate, polyamide, triacetylcellulose, polymethylmethacrylate, or polyethylene terephthalate. The upper film may be configured to absorb external impact applied to the front surface of the display device DD. In an embodiment of the disclosure, the display module DM may include a color filter replacing a polarizing film as a light-reflecting reduction component, which may reduce the front impact resistance of the display device DD. The upper film may compensate for the reduced impact resistance by applying the color filter.

The upper member UM may overlap the bezel area BZA and the transmissive area TA shown in FIG. 2. The upper member UM may partially overlap the bezel area BZA. A portion of the bezel pattern BM may be exposed from the upper member UM. In an embodiment of the disclosure, the upper member UM may be omitted. In an embodiment, the upper member UM may be replaced with an optical film that includes a polarizer and a retarder.

Although not explicitly illustrated, an adhesive layer configured to bond the upper member UM and the window WM may be disposed between the upper member UM and the window WM. The adhesive layer may be a pressure-sensitive adhesive film (PSA) or an optically clear adhesive (OCA).

The display module DM may be disposed below the upper member UM. The display module DM may overlap the bezel area BZA and the transmissive area TA. The display module DM may be completely overlapped by the upper member UM within the bezel area BZA. Side surfaces of the display module DM may be aligned with side surfaces of the upper member UM, and in a planar view, corners of the display module DM may be aligned with corners of the upper member UM.

Within the bezel area BZA, the pad area PA of the display module DM may overlap the upper member UM. A portion of the display module DM corresponding to the pad area PA may be bonded to the lower surface of the upper member UM by the adhesive layer. As the pad area PA overlaps the upper member UM and a portion of the display module DM overlapping the pad area PA is bonded to the upper member UM, the upper member UM may sufficiently support the pad area PA when the circuit board FCB is bonded to the pad area PA.

The lower member LM may include a lower film PF and a cover panel CP. In an embodiment, the lower member LM may further include a support plate and a digitizer. The lower film PF may be configured to expose the pad area PA of the display module DM. The lower film PF may have a smaller size than the display module DM. For example, the lower film PF may overlap only the display area DM-DA of the display module DM. An open area PF-OP corresponding to the non-display area DM-NDA may be defined in the lower film PF. In an embodiment, the lower film PF may have a size substantially corresponding to the display module DM. In such a case, an open area PF-OP corresponding to the pad area PA may be defined in the lower film PF. The pad area PA may be exposed through the open area PF-OP.

The cover panel CP may be disposed below the lower film PF. The cover panel CP may enhance resistance against compressive force generated by external pressing. Therefore, the cover panel CP may be configured to prevent deformation of the display module DM. The cover panel CP may include a flexible plastic material such as polyimide or polyethylene terephthalate. The cover panel CP may be a colored film with low light transmittance and may be configured to absorb incident light from the outside. For example, the cover panel CP may be a black synthetic resin film. When viewing the display device DD from the upper side of the window WM, components disposed below the cover panel CP may not be visible to the user.

Although not explicitly illustrated, the lower member LM may further include a support plate disposed below the cover panel CP. The support plate may include a high-strength metal material. The support plate may also include a fiber-reinforced composite. The support plate may include reinforcing fibers disposed inside a matrix portion. The reinforcing fibers may be carbon fibers or glass fibers. The matrix portion may include a polymer resin. The matrix portion may include a thermoplastic resin, such as, for example, a polyamide-based resin or a polypropylene-based resin. The fiber-reinforced composite may be carbon fiber reinforced plastic (CFRP) or glass fiber reinforced plastic (GFRP).

A main circuit board MCB may be disposed on a lower surface of the circuit board FCB. The circuit board FCB may include an insulating film (not shown) and conductive wiring (not shown) mounted on the insulating film. The main circuit board MCB may include signal lines (not shown) and electronic components (not shown). The electronic components (not shown) may be connected to the signal lines and electrically connected to the display module DM. The electronic components (not shown) may generate or process various electrical signals, such as signals for generating an image or signals for detecting an external input. The main circuit board MCB may be configured as a single board corresponding to each type of electrical signal to be generated and processed or may be implemented with three or more boards, but is not limited to any specific configuration.

The main circuit board MCB may include the driving chip DIC shown in FIG. 2 mounted thereon.

Referring to FIGS. 2 and 3, the circuit board FCB may be bonded on the rear surface of the display module DM (rear-surface bonding). In an embodiment of the disclosure, the display module DM may not be bent in the non-display area DM-NDA.

FIG. 4 illustrates a simplified cross-sectional view of a display module DM according to an embodiment of the disclosure. Referring to FIG. 4, the display module DM may include a display panel DP and an input sensing layer ISL. The display panel DP may include a base layer BL, a circuit layer DP-CL, a display element layer DP-ED, and an encapsulation layer TFE.

The base layer BL may be a component configured to provide a base surface on which the circuit layer DP-CL is disposed. The base layer BL may be a flexible substrate capable of bending, folding, and/or rolling. The base layer BL may be, for example, a glass substrate, a metal substrate, or a polymer substrate. However, the embodiments of the present disclosure are not limited thereto, and the base layer BL may be an inorganic layer, an organic layer, or a composite material layer.

The base layer BL may have a multilayer structure. For example, the base layer BL may include a first synthetic resin layer, a second synthetic resin layer, and inorganic layers disposed therebetween. Each of the first and second synthetic resin layers may include, but not limited to, a polyimide-based resin.

The circuit layer DP-CL may be disposed on the base layer BL. The circuit layer DP-CL may include multiple insulating layers, multiple semiconductor patterns, multiple conductive patterns, and signal lines. The circuit layer DP-CL may include a driving circuit for pixels. Hereinafter, unless otherwise specified, component A and component B disposed on the same layer are interpreted to have been formed by the same process, thereby including the same material or having the same stacking structure. Conductive patterns or semiconductor patterns disposed on the same layer may be interpreted similarly.

The display element layer DP-ED may be disposed on the circuit layer DP-CL. The display element layer DP-ED may include light-emitting diodes. For example, the light-emitting diodes may include organic light-emitting materials, inorganic light-emitting materials, organic-inorganic hybrid light-emitting materials, quantum dots, quantum rods, micro-LEDs, or nano-LEDs.

The encapsulation layer TFE may be disposed on the display element layer DP-ED. The encapsulation layer TFE may be configured to protect the display element layer DP-ED, that is, the light-emitting diodes, from foreign substances such as moisture, oxygen, and dust particles. The encapsulation layer TFE may include at least one inorganic encapsulation layer. The encapsulation layer TFE may have a stacked structure including a first inorganic encapsulation layer, an organic encapsulation layer, and a second inorganic encapsulation layer.

The input sensing layer ISL may be directly disposed on the display panel DP. The input sensing layer ISL may be configured to detect a user's input using, for example, an electromagnetic induction technique or a capacitive technique. The display panel DP and the input sensing layer ISL may be formed through consecutive processes. In this context, “directly disposed” may mean that no third component is interposed between the input sensing layer ISL and the display panel DP. For example, an adhesive layer may not be interposed between the input sensing layer ISL and the display panel DP.

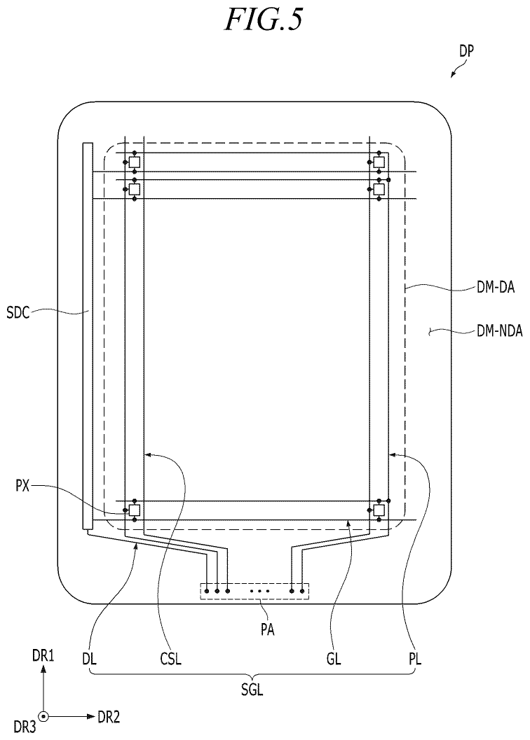

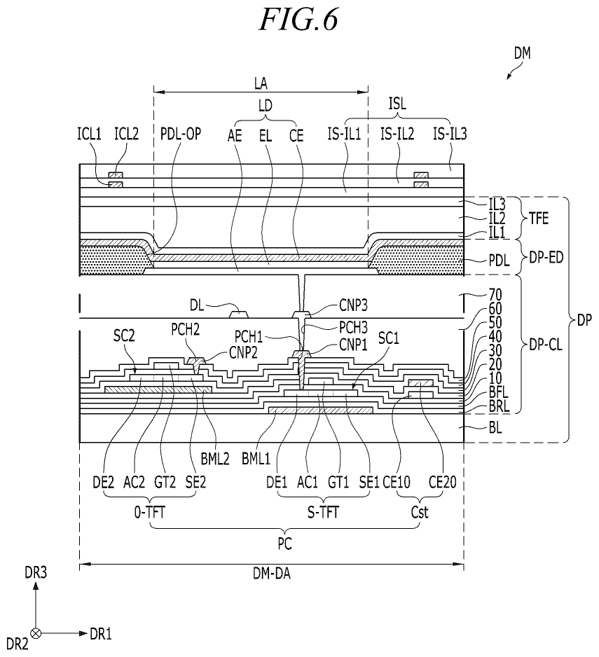

FIG. 5 illustrates a plan view of a display panel DP according to an embodiment of the disclosure. FIG. 6 illustrates a cross-sectional view of a display module DM according to an embodiment of the disclosure. As illustrated in FIG. 5, the display panel DP may include a scan driving circuit SDC, a plurality of signal lines SGL, and a plurality of pixels PX. The plurality of pixels PX may be disposed in the display area DM-DA. Each of the pixels PX may include a light-emitting diode and a pixel driving circuit connected to the light-emitting diode. The scan driving circuit SDC, the plurality of signal lines SGL, and the pixel driving circuit may be included in the circuit layer DP-CL (shown in FIG. 4).

The scan driving circuit SDC may include a gate driving circuit. The gate driving circuit may be configured to generate a plurality of scan signals and sequentially output the plurality of scan signals to a plurality of scan lines GL, which will be described later. The scan driving circuit SDC may further include a light-emission driving circuit that is distinguished from the gate driving circuit. The light-emission driving circuit may be configured to output scan signals to another group of scan lines.

The scan driving circuit SDC may include a plurality of thin-film transistors formed through the same process as the pixel driving circuit, such as a low-temperature polycrystalline silicon (LTPS) process or a low-temperature polycrystalline oxide (LTPO) process.

The plurality of signal lines SGL may include scan lines GL, data lines DL, a power line PL, and a control signal line CSL. Each scan line GL may be connected to a corresponding pixel PX among the plurality of pixels PX, and each data line DL may be connected to a corresponding pixel PX among the plurality of pixels PX. The power line PL may be connected to the plurality of pixels PX. The data lines DL may be configured to provide data signals to the pixels PX. The control signal line CSL may be configured to provide control signals to the scan driving circuit SDC.

The power line PL may be provided in plurality. For example, the power line PL may include a first power line configured to receive a first power voltage and a second power line configured to receive a second power voltage having a higher level than the first power voltage. The first power voltage may be provided to the pixels PX through the first power line, and the second power voltage may be provided to the pixels PX through the second power line. Although FIG. 5 illustrates a single control signal line CSL for illustrative purposes, the control signal line CSL may be provided in plurality.

The scan lines GL, the data lines DL, and the power line PL may overlap both the display area DM-DA and the non-display area DM-NDA, whereas the control signal line CSL may overlap the non-display area DM-NDA. The terminal ends of the plurality of signal lines SGL may be aligned at one side of the non-display area DM-NDA. Each of the plurality of signal lines SGL may have an integrated shape but may include multiple segments disposed on different layers. The segments differentiated by an insulating layer may be connected through a contact hole penetrating the insulating layer. For example, the data lines DL may include a first line portion (not shown) disposed in the display area DM-DA and a second line portion (not shown) disposed in the non-display area DM-NDA on a different layer from the first line portion. The first line portion and the second line portion may include different materials and have different stacking structures.

The plurality of signal lines SGL may be electrically connected to the main circuit board MCB (shown in FIG. 3) through the pad area PA.

FIG. 6 illustrates a cross-sectional view of the display module DM corresponding to the pixel PX shown in FIG. 5. Referring to FIG. 6, a pixel driving circuit PC configured to drive a light-emitting diode LD may include a plurality of pixel driving elements. The pixel driving circuit PC may include a plurality of transistors S-TFT, O-TFT and a capacitor Cst. The transistors S-TFT, O-TFT may include a silicon transistor S-TFT and an oxide transistor O-TFT. FIG. 6 exemplarily illustrates the silicon transistor S-TFT and the oxide transistor O-TFT. However, the configuration of the pixel driving circuit PC is not necessarily limited to what is illustrated herein. In an embodiment, the pixel driving circuit PC may include only one type of transistor among the silicon transistor S-TFT and the oxide transistor O-TFT.

The base layer BL may be provided as a single layer. The base layer BL may include a synthetic resin such as polyimide. The base layer BL may be formed by coating a synthetic resin layer on a working substrate (or carrier substrate). Once subsequent processes complete the display module DM, the working substrate may be removed.

A first shielding electrode BML1 may be disposed on the base layer BL. The first shielding electrode BML1 may be configured to receive a bias voltage. The first shielding electrode BML1 may be also configured to receive a first power voltage. The first shielding electrode BML1 may be configured to block an electrical potential caused by polarization from affecting the silicon transistor S-TFT. Additionally, the first shielding electrode BML1 may be configured to block external light from reaching the silicon transistor S-TFT. In an embodiment, the first shielding electrode BML1 may be an isolated type of floating electrode, separated from other electrodes or wirings. The first shielding electrode BML1 may be disposed to correspond to the silicon transistor S-TFT. The first shielding electrode BML1 may include a metal such as, for example, as molybdenum.

A barrier layer BRL may be disposed on the base layer BL and the first shielding electrode BML1. The barrier layer BRL may be configured to prevent foreign substances from flowing in from the outside. The barrier layer BRL may include at least one inorganic layer. The barrier layer BRL may include a silicon oxide layer and a silicon nitride layer. The silicon oxide layer and the silicon nitride layer may each be provided in plurality and may be alternately stacked.

A buffer layer BFL may be disposed on the barrier layer BRL. The buffer layer BFL may be configured to prevent metal atoms or impurities from diffusing from the base layer BL into a first semiconductor pattern SC1. The buffer layer BFL may include at least one inorganic layer. The buffer layer BFL may include a silicon oxide layer and a silicon nitride layer.

The first semiconductor pattern SC1 may be disposed on the buffer layer BFL. The first semiconductor pattern SC1 may include silicon semiconductor material, such as, for example, amorphous silicon or polycrystalline silicon. For example, the first semiconductor pattern SC1 may include low-temperature polycrystalline silicon (LTPS).

The first semiconductor pattern SC1 may have different electrical properties depending on doping. The first semiconductor pattern SC1 may include a first region with high conductivity and a second region with low conductivity. The first region may be doped with an N-type or P-type dopant. A P-type transistor may include a doped region with a P-type dopant, and an N-type transistor may include a doped region with an N-type dopant. The second region may be an undoped region or a region doped with a lower concentration compared to the first region. In an embodiment, the first semiconductor pattern SC1 may be an N-type transistor.

The first region may have greater conductivity than the second region, and the first region may substantially function as an electrode or a signal line. The second region may substantially function as a channel region (or active region) of the transistor. In other words, a portion of the first semiconductor pattern SC1 may serve as a transistor channel, another portion may serve as a source or drain of the transistor, and yet another portion may serve as a connection electrode or connection signal line.

A source region SE1, a channel region AC1 (or active region), and a drain region DE1 of the silicon transistor S-TFT may be formed from the first semiconductor pattern SC1. In a cross-sectional view, the source region SE1 and the drain region DE1 may extend in opposite directions from the channel region AC1.

A first insulating layer 10 may be disposed on the buffer layer BFL. The first insulating layer 10 may cover the first semiconductor pattern SC1. The first insulating layer 10 may be an inorganic layer. The first insulating layer 10 may be a single layer of silicon oxide. In addition to the first insulating layer 10, the inorganic layers of the circuit layer DP-CL, which will be described later, may have a single-layer or multilayer structure and may include at least one of the above-described materials, but the structures and materials for these layers are not limited thereto.

A gate GT1 of the silicon transistor S-TFT may be disposed on the first insulating layer 10. The gate GT1 may be part of a metal pattern and may overlap the channel region AC1. The gate GT1 may function as a mask during the doping process of the first semiconductor pattern SC1. A first electrode CE10 of a storage capacitor Cst may also be disposed on the first insulating layer 10. In an embodiment, unlike the illustration in FIG. 6, the first electrode CE10 may have an integrated shape with the gate GT1.

A second insulating layer 20 may be disposed on the first insulating layer 10 and may cover the gate GT1. In an embodiment, an upper electrode overlapping the gate GT1 may be further disposed on the second insulating layer 20. A second electrode CE20 overlapping the first electrode CE10 may be disposed on the second insulating layer 20. The upper electrode may have an integrated shape with the second electrode CE20 in a planar view.

A second shielding electrode BML2 may be disposed on the second insulating layer 20. The second shielding electrode BML2 may be disposed to correspond to the oxide transistor O-TFT. In an embodiment, the second shielding electrode BML2 may be omitted. In an embodiment, the first shielding electrode BML1 may extend below the oxide transistor O-TFT to replace the second shielding electrode BML2.

A third insulating layer 30 may be disposed on the second insulating layer 20. A second semiconductor pattern SC2 may be disposed on the third insulating layer 30. The second semiconductor pattern SC2 may include a channel region AC2 of the oxide transistor O-TFT. The second semiconductor pattern SC2 may include a metal oxide semiconductor. The second semiconductor pattern SC2 may include a transparent conductive oxide such as indium tin oxide (ITO), indium zinc oxide (IZO), indium gallium zinc oxide (IGZO), zinc oxide (ZnOx), or indium oxide (In₂O₃).

The metal oxide semiconductor may include multiple regions SE2, AC2, DE2, distinguished by whether the transparent conductive oxide has been reduced. A region in which the transparent conductive oxide has been reduced (hereinafter referred to as the reduction region) may have higher conductivity than a region in which the transparent conductive oxide has not been reduced (hereinafter referred to as the non-reduction region). The reduction region may substantially function as a source/drain of the transistor or a signal line, while the non-reduction region may substantially function as a semiconductor region (or channel) of the transistor. In other words, a portion of the second semiconductor pattern SC2 may serve as a semiconductor region of the transistor, another portion may serve as the source region SE2 or drain region DE2 of the transistor, and yet another portion may serve as a signal transfer region.

A fourth insulating layer 40 may be disposed on the third insulating layer 30. As shown in FIG. 6, the fourth insulating layer 40 may cover the second semiconductor pattern SC2. In an embodiment, the fourth insulating layer 40 may overlap a gate GT2 of the oxide transistor O-TFT. The fourth insulating layer 40 may be an insulating pattern exposed by the source region SE2 and drain region DE2 of the oxide transistor O-TFT.

The gate GT2 of the oxide transistor O-TFT may be disposed on the fourth insulating layer 40. The gate GT2 of the oxide transistor O-TFT may be part of a metal pattern and may overlap the channel region AC2.

A fifth insulating layer 50 may be disposed on the fourth insulating layer 40 and may cover the gate GT2. Each of the first insulating layer 10 to the fifth insulating layer 50 may be an inorganic layer.

A conductive layer may be disposed on the fifth insulating layer 50. In the present disclosure, the conductive layer may include a first connection pattern CNP1 and a second connection pattern CNP2. The first connection pattern CNP1 and the second connection pattern CNP2 may be formed through the same process and thus may have the same material and stacking structure. The first connection pattern CNP1 may be connected to the drain region DE1 of the silicon transistor S-TFT through a first pixel contact hole PCH1 penetrating the first to fifth insulating layers 10, 20, 30, 40, 50. The second connection pattern CNP2 may be connected to the source region SE2 of the oxide transistor O-TFT through a second pixel contact hole PCH2 penetrating the fourth and fifth insulating layers 40, 50. However, the connection relationship of the first connection pattern CNP1 and the second connection pattern CNP2 with the silicon transistor S-TFT and the oxide transistor O-TFT is not necessarily limited thereto.

A sixth insulating layer 60 may be disposed on the fifth insulating layer 50. A third connection pattern CNP3 may be disposed on the sixth insulating layer 60. The third connection pattern CNP3 may be connected to the first connection pattern CNP1 through a third pixel contact hole PCH3 penetrating the sixth insulating layer 60. A data line DL may be disposed on the sixth insulating layer 60. A seventh insulating layer 70 may be disposed on the sixth insulating layer 60 and may cover the third connection pattern CNP3 and the data line DL. The third connection pattern CNP3 and the data line DL may be formed through the same process and, therefore, may have the same material and stacking structure. The sixth insulating layer 60 and the seventh insulating layer 70 may each be an organic layer.

The first shielding electrode BML1, the gate GT1 of the silicon transistor S-TFT, the second electrode CE20, and the gate GT2 of the oxide transistor O-TFT may include a metal such as molybdenum (Mo), an alloy containing molybdenum, titanium (Ti), or an alloy containing titanium, which has good heat resistance. The first connection pattern CNP1 and the second connection pattern CNP2 may include aluminum (Al), which has high electrical conductivity. The first connection pattern CNP1 and the second connection pattern CNP2 may have a three-layer structure stacked with titanium/aluminum/titanium.

The light-emitting diode LD may include an anode AE (or a first electrode), an emission layer EL, and a cathode CE (or a second electrode). The anode AE of the light-emitting diode LD may be disposed on the seventh insulating layer 70. The anode AE may be a transparent electrode, a semi-transparent electrode, or a reflective electrode. The anode AE may include a sequentially stacked structure of ITO/Ag/ITO. The positions of the anode AE and the cathode CE may be interchangeable.

A pixel defining layer PDL may be disposed on the seventh insulating layer 70. The pixel defining layer PDL may be an organic layer and may have light-absorbing properties. For example, the pixel defining layer PDL may have a black color and may include a black coloring agent. The black coloring agent may include black dye and/or black pigment. The black pigment may include carbon black, a metal such as chromium, or oxides thereof. The pixel defining layer PDL may correspond to a light-blocking pattern having light-shielding properties.

The pixel defining layer PDL may cover a portion of the anode AE. For example, a pixel opening PDL-OP exposing a portion of the anode AE may be defined in the pixel defining layer PDL. A light-emission area LA may be defined to correspond to the pixel opening PDL-OP. In an embodiment of the disclosure, a hole control layer (not shown) may be disposed between the anode AE and the emission layer EL. The hole control layer may include at least one of a hole transport layer and a hole injection layer. An electron control layer (not shown) may be disposed between the emission layer EL and the cathode CE. The electron control layer may include at least one of an electron transport layer and an electron injection layer.

An encapsulation layer TFE may cover the light-emitting diode LD. The encapsulation layer TFE may include a first encapsulation insulating layer IL1, a second encapsulation insulating layer IL2, and a third encapsulation insulating layer IL3. However, the encapsulation layer TFE is not necessarily limited thereto and may further include multiple inorganic and organic layers.

The first encapsulation insulating layer IL1 may be an inorganic layer. The first encapsulation insulating layer IL1 may be configured to prevent external moisture or oxygen from penetrating into the light-emitting diode LD. For example, the first encapsulation insulating layer IL1 may include silicon nitride, silicon oxide, or a compound including a combination thereof. The first encapsulation insulating layer IL1 may be formed by a chemical vapor deposition process.

The second encapsulation insulating layer IL2 may be an organic layer. The second encapsulation insulating layer IL2 may be disposed on the first encapsulation insulating layer IL1 to be in contact with the first encapsulation insulating layer IL1. The second encapsulation insulating layer IL2 may provide a flat surface over the first encapsulation insulating layer IL1. Any surface irregularities or particles present on an upper surface of the first encapsulation insulating layer IL1 may be covered by the second encapsulation insulating layer IL2. Accordingly, the surface condition of the first encapsulation insulating layer IL1 may not influence on the elements formed on the second encapsulation insulating layer IL2. Additionally, the second encapsulation insulating layer IL2 may reduce the stress between adjacent layers. The second encapsulation insulating layer IL2 may be formed through a solution process such as spin coating, slit coating, and/or inkjet printing.

The third encapsulation insulating layer IL3 may be disposed on the second encapsulation insulating layer IL2 and may cover the second encapsulation insulating layer IL2. The third encapsulation insulating layer IL3 may be formed more stably on a relatively flat surface than when disposed directly on the first encapsulation insulating layer IL1. The third encapsulation insulating layer IL3 may be configured to encapsulate moisture released from the second encapsulation insulating layer IL2 to prevent leakage to the outside.

The third encapsulation insulating layer IL3 may be optically transparent. For example, the third encapsulation insulating layer IL3 may have a visible light transmittance of approximately 90 % or greater. The third encapsulation insulating layer IL3 may have a relatively higher light transmittance than the first encapsulation insulating layer IL1. The third encapsulation insulating layer IL3 may be an inorganic layer and may include silicon oxide (SiOx) or silicon oxynitride (SiON). The third encapsulation insulating layer IL3 may be formed by a chemical vapor deposition process. The first encapsulation insulating layer IL1, the second encapsulation insulating layer IL2, and the third encapsulation insulating layer IL3 may each include multiple layers and are not necessarily limited to any one embodiment.

The input sensing layer ISL may include at least one conductive layer (or at least one sensor conductive layer) and at least one insulating layer (or at least one sensor insulating layer). In the present embodiment, the input sensing layer ISL may include a first insulating layer IS-IL1, a first conductive layer ICL1, a second insulating layer IS-IL2, a second conductive layer ICL2, and a third insulating layer IS-IL3. FIG. 6 schematically illustrates conductive lines of the first conductive layer ICL1 and the second conductive layer ICL2.

The first insulating layer IS-IL1 may be disposed directly on the display panel DP. The first insulating layer IS-IL1 may be an inorganic layer including at least one of silicon nitride, silicon oxynitride, and silicon oxide. The first conductive layer ICL1 and the second conductive layer ICL2 may each have a single-layer structure or a multilayer structure stacked along the third direction DR3. The first conductive layer ICL1 and the second conductive layer ICL2 may include conductive lines defining a mesh-patterned electrode. The conductive lines of the first conductive layer ICL1 and the second conductive layer ICL2 may or may not be connected through a contact hole penetrating the second insulating layer IS-IL2. The connection relationship between the conductive lines of the first conductive layer ICL1 and the second conductive layer ICL2 may be determined based on the type of sensor formed with the input sensing layer ISL.

The first conductive layer ICL1 and the second conductive layer ICL2, when formed as a single-layer structure, may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnOx), or indium zinc tin oxide (IZTO). Additionally, the transparent conductive layer may include a conductive polymer such as PEDOT, metal nanowires, and/or graphene.

The first conductive layer ICL1 and the second conductive layer ICL2, when formed as a multilayer structure, may include metal layers. The metal layers may have, for example, a three-layer structure of titanium/aluminum/titanium. The multilayer structure of conductive layer may include at least one metal layer and at least one transparent conductive layer. The second insulating layer IS-IL2 may be disposed between the first conductive layer ICL1 and the second conductive layer ICL2. The third insulating layer IS-IL3 may cover the second conductive layer ICL2. In an embodiment of the disclosure, the third insulating layer IS-IL3 may be omitted. The second insulating layer IS-IL2 and the third insulating layer IS-IL3 may each include an inorganic layer or an organic layer.

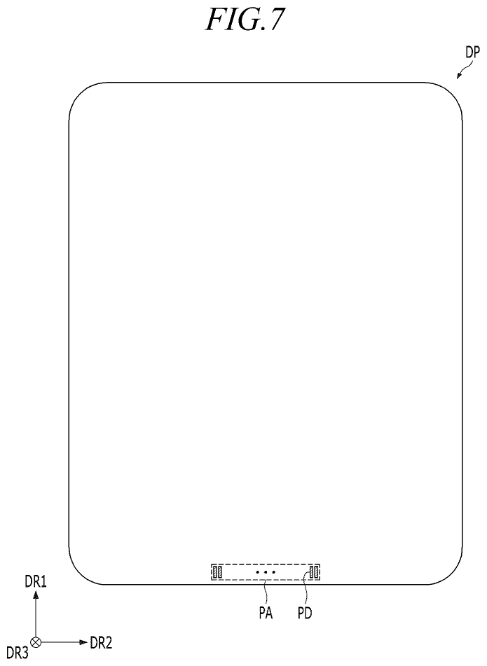

FIG. 7 illustrates a plan view of a display panel DP according to an embodiment of the disclosure. Specifically, FIG. 7 is a plan view of the display panel DP viewed from the third direction DR3. Referring to FIG. 7, a pad electrode PD may be disposed on the rear surface of the display panel DP. Specifically, the pad electrode PD may be disposed in the pad area PA. The pad electrode PD may be provided in plurality and may be arranged along the second direction DR2.

The plurality of signal lines SGL (shown in FIG. 5) disposed on the display panel DP may be electrically connected to the circuit board FCB (shown in FIG. 3) through the pad area PA. For example, the plurality of signal lines SGL may be disposed in the pad area PA and may be connected to the pad electrodes PD, which are spaced apart from each other along the first direction DR1, through connection electrodes or the like. Although not explicitly illustrated, the pad electrodes PD may be disposed on the rear surface of the display panel DP and may be electrically connected to the flexible circuit board FCB (shown in FIG. 2).

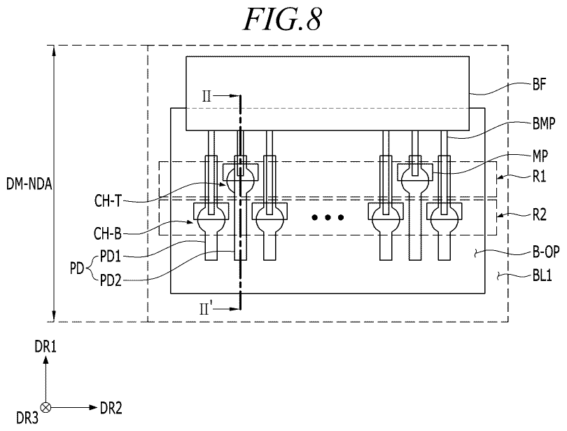

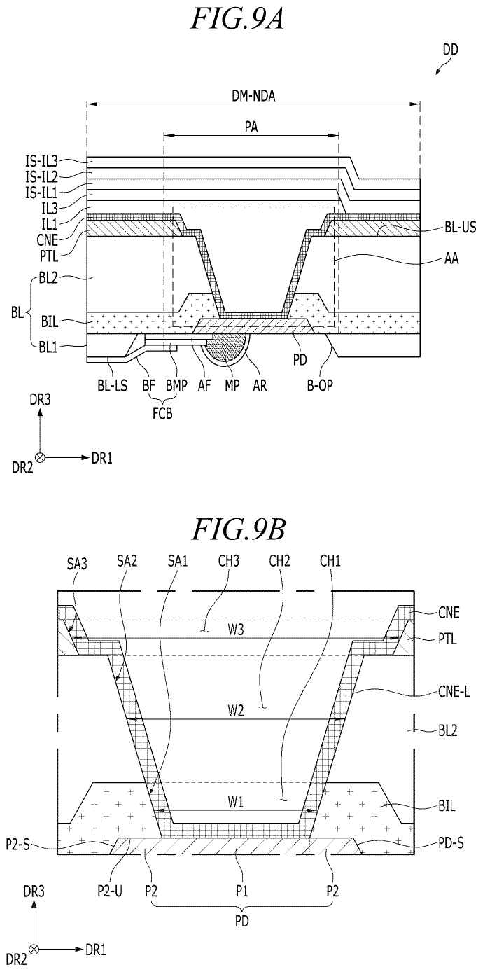

FIG. 8 illustrates an enlarged view of a portion of a display device DD according to an embodiment of the disclosure. FIG. 9A is a cross-sectional view of a portion of the display device DD taken along line II-II′ of FIG. 8. FIG. 9B illustrates an enlarged view of the AA′ region shown in FIG. 9A. FIGS. 8 and 9A illustrate a state in which the circuit board FCB is attached to the display panel DP. The following description omits redundant details described above.

Referring to FIG. 8, the display device DD according to an embodiment of the disclosure may include a plurality of pad electrodes PD. For convenience of explanation, components overlapping in a planar view are simultaneously illustrated in FIG. 8. The pad electrodes PD may be arranged in a zigzag pattern in a planar view. For example, as shown in FIG. 8, among first and second pad electrodes PD1, PD2, the first pad electrode PD1 may have a bottom contact hole CH-B in a second row R2, which is relatively farther than a first row R1 from the base film BF. Moreover, among the first and second pad electrodes PD1, PD2, the second pad electrode PD2 may have a top contact hole CH-T in the first row R1, which is relatively closer than the second row R2 from the base film BF.

As the pad electrodes PD1, PD2 are arranged in a zigzag pattern in a planar view, the pad electrodes PD1, PD2 may be closely spaced with electrical contact prevented between the pad electrodes PD1, PD2.

The pad electrodes PD and the first shielding electrode BML1 (shown in FIG. 6) may be disposed on the same layer. The pad electrodes PD and the first shielding electrode BML1 may be formed through the same process. For example, a single metal layer may be placed on the base layer BL, and the metal layer may be patterned such that the pad electrodes PD are formed in the non-display area DM-NDA while the first shielding electrode BML1 is formed in the display area DM-DA. Although not explicitly illustrated, the pad electrodes PD may be electrically connected to the data lines DL (shown in FIG. 5) and other components through a connection electrode CNE disposed on the pad electrodes PD.

The pad electrodes PD may be arranged in the non-display area DM-NDA. More specifically, the pad electrodes PD may be arranged in the pad area PA. The pad electrodes PD may be exposed to the outside through a first surface BL-LS (see FIG. 9A) of the base layer BL to facilitate back bonding with the circuit board FCB. However, the disclosure is not necessarily limited thereto, and the pad electrodes PD may be exposed externally through contact holes or other structures instead of being directly exposed. The first surface BL-LS of the base layer BL may face a second surface BL-US (see FIG. 9A) of the base layer BL in the third direction DR3.

In an embodiment, the pad electrodes PD may overlap the non-display area DM-NDA.

Referring to FIGS. 9A and 9B, the base layer BL may include a first base layer BL1, a base insulating layer BIL, and a second base layer BL2, which are sequentially stacked. The base insulating layer BIL may be disposed on the first base layer BL1, and the second base layer BL2 may be disposed on the base insulating layer BIL.

In an embodiment, the first base layer BL1 and the second base layer BL2 may include an inorganic material, a synthetic resin material, or an organic material. For example, the first base layer BL1 and the second base layer BL2 may include silicon nitride, silicon oxynitride, or silicon oxide. Amorphous silicon (a-Si) may also be included. The first base layer BL1 and the second base layer BL2 may each include multiple layers.

The first base layer BL1 may provide the first surface BL-LS of the base layer BL, and an opening B-OP below the pad electrodes PD that exposes the pad electrodes PD to the outside may be defined in the first base layer BL1. A portion of the base insulating layer BIL may be exposed externally through the opening B-OP.

The base insulating layer BIL may be disposed on a portion of the first base layer BL1 and a portion of the pad electrode PD and may partially cover the pad electrode PD. A first contact hole CH1, which extends to the pad electrode PD and through which a portion of the pad electrode PD is exposed, may be defined in the base insulating layer BIL.

In an embodiment, the base insulating layer BIL may include an amorphous silicon layer and a silicon oxide layer disposed on the amorphous silicon layer. The silicon oxide layer may have a thickness of at least 100 Å. In an embodiment, the base insulating layer BIL may include at least one of silicon oxide, silicon nitride, and silicon oxynitride.

The second base layer BL2 may be disposed on the base insulating layer BIL, and a second contact hole CH2 may be defined in the second base layer BL2. In an embodiment, the second base layer BL2 may include an organic material.

A protection layer PTL may be disposed on the second base layer BL2, and a third contact hole CH3 may be defined in the protection layer PTL. In an embodiment, the protection layer PTL may be disposed in direct contact with the second base layer BL2. The protection layer PTL may at least partially overlap the second base layer BL2. The protection layer PTL may be thinner than the second base layer BL2.

In an embodiment, the protection layer PTL may include at least one inorganic layer. For example, the inorganic layer may include silicon nitride, silicon oxynitride, and/or silicon oxide. Amorphous silicon (a-Si) may also be included.

In an embodiment, the second base layer BL2 may be thicker than the protection layer PTL.

Referring to FIG. 9B, in an embodiment, the pad electrode PD may include a first portion P1 and a second portion P2. In an embodiment, the first portion P1 may be in direct contact with the connection electrode CNE, while the second portion P2 may not be in contact with the connection electrode CNE. The first portion P1 may overlap the first contact hole CH1 in a planar view. In an embodiment, the first portion P1 and the second portion P2 may extend parallel to a plane defined by the first direction DR1 and the second direction DR2.

In an embodiment, the second portion P2 may be disposed beneath the base insulating layer BIL, and an upper surface P2-U of the second portion P2 may be in direct contact with the base insulating layer BIL. In an embodiment, the base insulating layer BIL may be in direct contact with a side surface P2-S of the second portion P2. In an embodiment, the base insulating layer BIL may cover the second portion P2.

According to an embodiment of the disclosure, the pad electrode PD may be disposed on the first base layer BL1, and the base insulating layer BIL may be disposed on a portion of the first base layer BL1 and a portion of the pad electrode PD. According to a method for manufacturing a display panel, which will be described later, the base insulating layer BIL may be formed after the pad electrode PD is formed, covering the second portion P2, which corresponds to an edge of the pad electrode PD, thereby being configured to prevent delamination or lifting of the pad electrode PD.

Referring to FIGS. 9A and 9B, the connection electrode CNE may be electrically connected to the pad electrodes PD through the contact holes CH1, CH2, CH3, which may include the first contact hole CH1, the second contact hole CH2, and the third contact hole CH3. The first contact hole CH1 may be formed in the base insulating layer BIL by penetrating the base insulating layer BIL. The second contact hole CH2 may be formed in the second base layer BL2 by penetrating the second base layer BL2. The third contact hole CH3 may be formed in the protection layer PTL by penetrating the protection layer PTL.

The first contact hole CH1 may be defined by a first side surface SA1 of the base insulating layer BIL, and a first width W1 of the first contact hole CH1 may be defined as the average distance between the first side surfaces SA1. The second contact hole CH2 may be defined by a second side surface SA2 of the second base layer BL2, and a second width W2 of the second contact hole CH2 may be defined as the average distance between the second side surfaces SA2. The third contact hole CH3 may be defined by a third side surface SA3 of the protection layer PTL, and a third width W3 of the third contact hole CH3 may be defined as the average distance between the third side surfaces SA3.

According to an embodiment, the second width W2 of the second contact hole CH2 and the third width W3 of the third contact hole CH3 may be different from each other. For example, the third width W3 may be greater than the second width W2. In an embodiment, during the formation of the second contact hole CH2 and the third contact hole CH3, the etching rates of the protection layer PTL and the second base layer BL2 may differ, resulting in a difference between the second width W2 and the third width W3. In an embodiment, the protection layer PTL may be etched before the second base layer BL2 is etched, leading to a difference between the second width W2 and the third width W3.

The first width W1 may be smaller than the second width W2. However, the disclosure is not necessarily limited thereto, and in some embodiments, the first width W1 and the second width W2 may have the same value. That is, in an embodiment, the first side surface SA1 and the second side surface SA2 may be linearly aligned parallel to the third direction DR3.

According to an embodiment, the insulating layers 10, 20, 30, 40, 50 (shown in FIG. 6) and the conductive layers CNP1, CNP2, BML2 (shown in FIG. 6) may not be disposed in the pad area PA. Although not explicitly illustrated, a photoresist may be placed before the protection layer PTL is formed, thereby preventing the insulating layers 10, 20, 30, 40, 50 (shown in FIG. 6) and the conductive layers CNP1, CNP2, BML2 (shown in FIG. 6) from being formed between the second base layer BL2 and the protection layer PTL. In an embodiment, a photoresist may be placed before the connection electrode CNE is formed, thereby preventing the insulating layers 10, 20, 30, 40, 50 (shown in FIG. 6) and the conductive layers CNP1, CNP2, BML2 (shown in FIG. 6) from being formed between the connection electrode CNE and the protection layer PTL. Accordingly, the connection electrode CNE, e.g., a lower surface CNE-L thereof, may be disposed directly on the first to third side surfaces SA1, SA2, SA3 without having any step difference, thereby preventing disconnection. Furthermore, it is possible to prevent poor connection between the connection electrode CNE and the pad electrodes PD caused by any residues from the insulating layers 10, 20, 30, 40, 50 (shown in FIG. 6) and the conductive layers CNP1, CNP2, BML2 (shown in FIG. 6), thereby improving the reliability of the display device DD.

The first contact hole CH1, the second contact hole CH2, and the third contact hole CH3 may overlap each other in a planar view. Additionally, the first to third contact holes CH1, CH2, CH3 may overlap the opening B-OP in a planar view. Referring to FIGS. 9A and 9B, the width of the opening B-OP is illustrated to be greater than the first to third widths W1, W2, W3. However, the disclosure is not necessarily limited thereto, and the width of the opening B-OP may be smaller than each of the first to third widths W1, W2, W3.

Referring to FIGS. 8 and 9A, the circuit board FCB may stay bent on the rear surface of the display panel DP when the circuit board FCB is attached to the display panel DP. An adhesive layer AF may be disposed between the circuit board FCB and the first surface BL-LS of the base layer BL. The circuit board FCB may be fixed to the first surface BL-LS of the base layer BL by the adhesive layer AF.

The circuit board FCB may include a base film BF and a bump electrode BMP disposed on the base film BF. The base film BF may be integrally formed and electrically connected to a plurality of bump electrodes BMP. In such a case, the base film BF may include a plurality of wiring lines inside. However, the disclosure is not necessarily limited thereto, and the base film BF may be merely attached to, but not electrically connected to, the plurality of bump electrodes BMP. In such a case, the base film BF may include a synthetic resin material, such as for example polyimide. The bump electrodes BMP may be disposed on the base film BF.

The bump electrodes BMP may overlap the pad electrodes PD in a planar view. The bump electrodes BMP may be electrically connected to the pad electrodes PD. The bump electrodes BMP may be formed to correspond to the pad electrodes PD. That is, one bump electrode BMP may correspond to one pad electrode PD. The bump electrodes BMP may extend in the first direction DR1 and be arranged in the second direction DR2. The planar areas of the pad electrodes PD may be larger than the planar areas of the bump electrodes BMP.

An adhesive layer AF may be disposed between the bump electrodes BMP and the pad electrodes PD. According to an embodiment of the disclosure, the adhesive layer AF may include a non-conductive material. For example, the adhesive layer AF may include a non-conductive film.

The bump electrodes BMP may be electrically connected to the pad electrodes PD. Specifically, the display device DD (shown in FIG. 2) may further include metal patterns MP that electrically connect the bump electrodes BMP and the pad electrodes PD. The metal patterns MP may be disposed on the pad electrodes PD and the bump electrodes BMP to electrically connect the pad electrodes PD and the bump electrodes BMP. The metal patterns MP may be provided in a quantity corresponding to the number of pad electrodes PD and the number of bump electrodes BMP.

Each metal pattern MP may be a cured pattern of metal ink. The metal patterns MP may include solder paste. The metal patterns MP may be formed from metal ink containing, for example, silver or copper. The metal patterns MP may be formed by curing and then patterning the metal ink. The metal patterns MP may be formed at a low temperature, enabling the pad electrodes PD and the bump electrodes BMP to be electrically connected and bonded simultaneously without requiring a high-temperature pressing process.

The display device DD of the present disclosure may further include an adhesive resin AR. The adhesive resin AR may include an optical clear resin. However, the material of the adhesive resin AR is not necessarily limited thereto and may include a conventional adhesive or adhesive agent. For example, the adhesive resin AR may include a pressure-sensitive adhesive (PSA) or an optical clear adhesive (OCA). The adhesive resin AR may cover the metal patterns MP that are exposed externally. Unlike the depiction in FIG. 9A, the adhesive resin AR may be formed to fill the opening B-OP. The adhesive resin AR may be formed to be in contact with the side surface of the first base layer BL1 to reduce the likelihood of cracks occurring inside the display device DD when the display device DD is subjected to an external impact and bent around the opening B-OP.

FIGS. 10 and 11 are enlarged views showing a portion of the display device according to an embodiment of the present disclosure. In the description below, any description provided above will not be redundantly provided.

Referring to FIG. 10, a connection electrode CNEa may be electrically connected to pad electrodes PD through contact holes CH1, CH2, CH3a. The first contact hole CH1 may be defined by the first side surface SA1 of the base insulating layer BIL, and the first width W1 of the first contact hole CH1 may be defined as the average distance between the first side surfaces SA1. The second contact hole CH2 may be defined by the second side surface SA2 of the second base layer BL2, and the second width W2 of the second contact hole CH2 may be defined as the average distance between the second side surfaces SA2. The third contact hole CH3a may be defined by a third side surface SA3a of a protection layer PTLa, and a third width W3a of the third contact hole CH3a may be defined as the average distance between the third side surfaces SA3a.

As illustrated, the first width W1 may be smaller than the second width W2, and the second width W2 may be smaller than the third width W3a. However, the disclosure is not necessarily limited thereto, and the first width W1, the second width W2, and the third width W3a may be the same. That is, the first side surface SA1, the second side surface SA2, and the third side surface SA3a may be linearly aligned parallel to the third direction DR3. As a result, the connection electrode CNEa may be disposed on the first side surface SA1, the second side surface SA2, and the third side surface SA3a without having any step difference, thereby preventing disconnection by the first side surface SA1, the second side surface SA2, and the third side surface SA3a.

Referring to FIG. 11, a connection electrode CNEb may be electrically connected to the pad electrodes PD through contact holes CH1, CH2b, CH3b. The first contact hole CH1 may be defined by the first side surface SA1 of the base insulating layer BIL, and the first width W1 of the first contact hole CH1 may be defined as the average distance between the first side surfaces SA1. The second contact hole CH2b may be defined by a second side surface SA2b of a second base layer BL2b, and a second width W2b of the second contact hole CH2b may be defined as the average distance between the second side surfaces SA2b. The third contact hole CH3b may be defined by a third side surface SA3b of a protection layer PTLb, and the third width W3b of the third contact hole CH3b may be defined as the average distance between the third side surfaces SA3b.

In the manufacturing process of the display device DD (shown in FIG. 2), the protection layer PTLb, the second base layer BL2b, and the base insulating layer BIL may be sequentially etched so that the first width W1 becomes smaller than the second width W2b, and the second width W2b becomes smaller than the third width W3b. As a result, an inverted taper profile due to differences in the etching rates of the protection layer PTLb, the second base layer BL2b, and the base insulating layer BIL may be prevented in the etching rates of the protection layer PTLb, the second base layer BL2b, and the base insulating layer BIL. Therefore, the connection electrode CNEb may be prevented from being disconnected due to the first side surface SA1, the second side surface SA2b, and the third side surface SA3b.

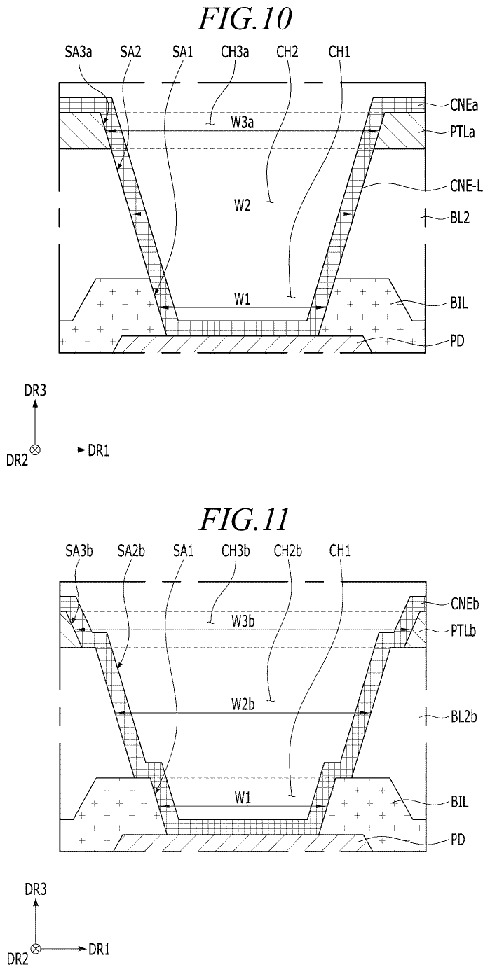

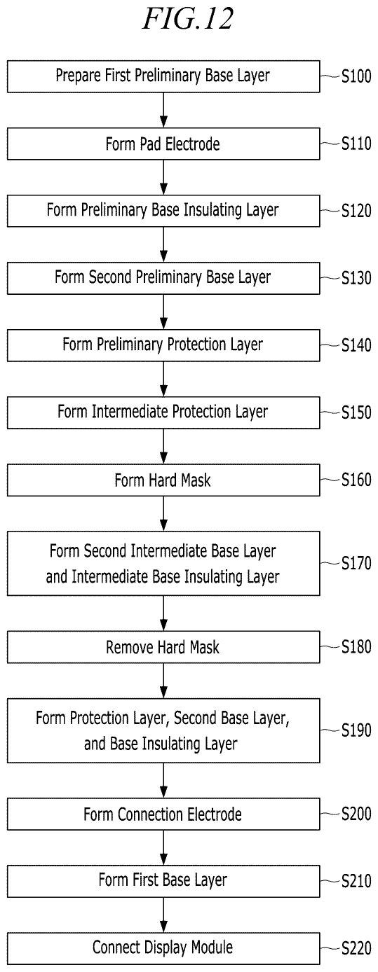

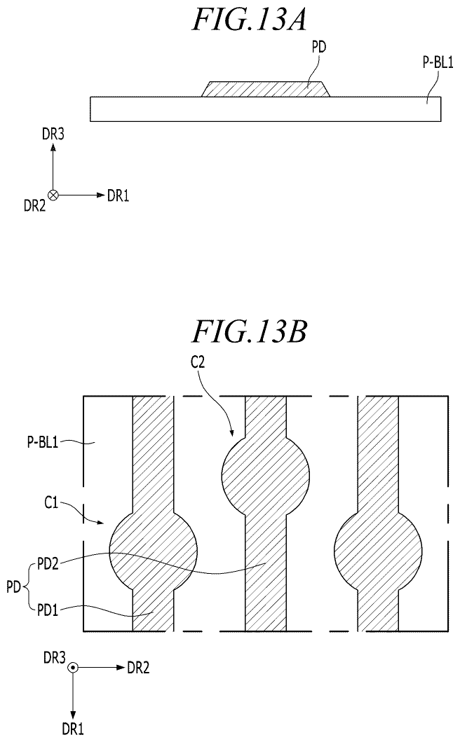

FIG. 12 is a flow diagram illustrating a method for manufacturing a display device according to an embodiment of the present disclosure. FIGS. 13 to 26 are schematic diagrams illustrating respective steps of the method for manufacturing a display device according to an embodiment.

Hereinafter, in describing the method for manufacturing a display device according to an embodiment with reference to FIGS. 12 to 26, the same reference numerals will be assigned to components identical to those described above, and redundant descriptions will be omitted.

Referring to FIG. 12, the method for manufacturing a display device according to an embodiment may include: preparing a first preliminary base layer (S100); forming a pad electrode (S110); forming a preliminary base insulating layer (S120); forming a second preliminary base layer (S130); forming a preliminary protection layer (S140); forming an intermediate protection layer (S150); forming a hard mask (S160); forming a second intermediate base layer and an intermediate base insulating layer (S170); removing the hard mask (S180); forming a protection layer, a second base layer, and a base insulating layer (S190); forming a connection electrode (S200); forming a first base layer (S210); and connecting a display module (S220).

FIG. 13A is a cross-sectional view illustrating a step of the method for manufacturing a display device according to an embodiment, and FIG. 13B is a plan view illustrating the same step as shown in FIG. 13A.

Referring to FIGS. 12 and 13A, in step S100, a first preliminary base layer P-BL1 may be prepared, and in step S110, a pad electrode PD may be directly formed on the first preliminary base layer P-BL1. For example, in step S110, a metal layer (not shown) may first be formed on the first preliminary base layer P-BL1 and then patterned to form the pad electrode PD. In an embodiment of the present disclosure, the pad electrode PD is disposed directly on the first preliminary base layer P-BL1, thereby preventing delamination or lifting of the pad electrode PD in subsequent processes.

Referring to FIGS. 13A and 13B, the pad electrodes PD may be provided in plurality, and the plurality of pad electrodes PD may be arranged in a zigzag pattern along the second direction DR2 in a planar view. Among the pad electrodes PD, a circular portion C1 of a first pad electrode PD1 may be a region where a lower contact hole CH-B (shown in FIG. 8) is formed in a subsequent process, and a circular portion C2 of a second pad electrode PD2 may be a region where an upper contact hole CH-T (shown in FIG. 8) is formed in a subsequent process.

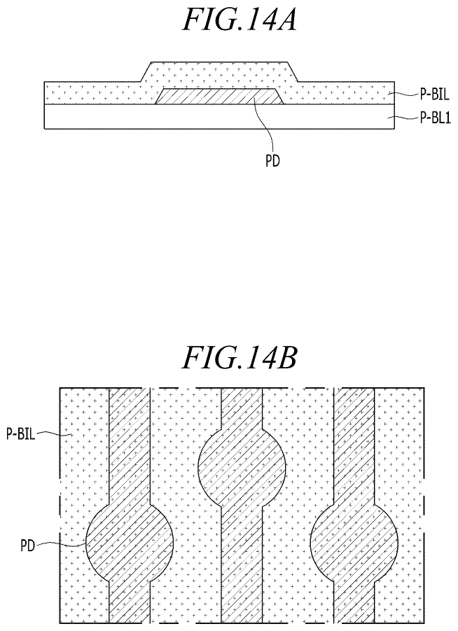

FIG. 14A is a cross-sectional view illustrating a step of the method for manufacturing a display device according to an embodiment, and FIG. 14B is a plan view illustrating the same step as shown in FIG. 14A. For convenience of description, in the plan views, lower structures covered by upper structures are also depicted together.

Referring to FIGS. 12 and 14A, in step S120, a preliminary base insulating layer P-BIL may be formed on the pad electrode PD and the first preliminary base layer P-BL1. Referring also to FIG. 14B, the preliminary base insulating layer P-BIL may be formed to cover the pad electrode PD.

Referring to FIGS. 12 and 15, in step S130, a second preliminary base layer P-BL2 may be formed on the preliminary base insulating layer P-BIL. A photoresist layer PR may be disposed on the second preliminary base layer P-BL2. Referring also to FIG. 6, insulating layers 10, 20, 30, 40, 50 and conductive layers CNP1, CNP2, BML2 may be disposed on the base layer BL of the present disclosure. However, the insulating layers 10, 20, 30, 40, 50 and the conductive layers CNP1, CNP2, BML2 may not be formed in the pad area PA (shown in FIG. 9A) by disposing the photoresist layer PR on the second preliminary base layer P-BL2. Subsequently, the photoresist layer PR may be removed.

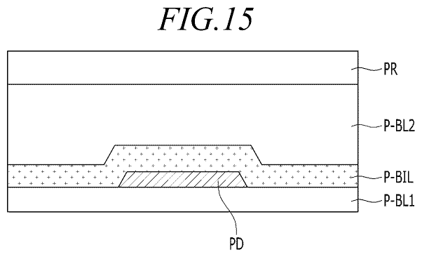

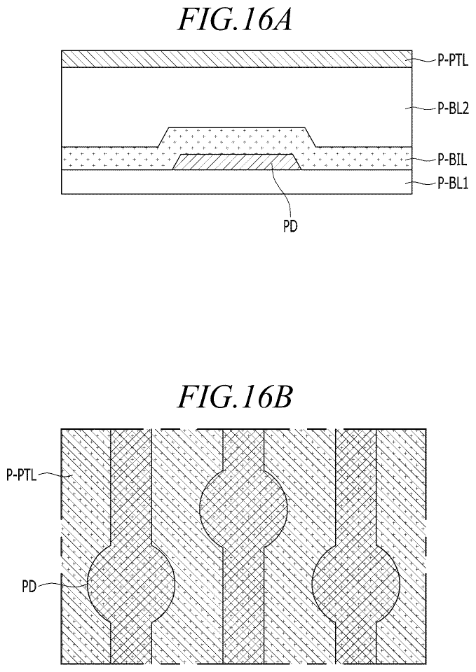

FIG. 16A is a cross-sectional view illustrating a step of the method for manufacturing a display device according to an embodiment, and FIG. 16B is a plan view illustrating the same step as shown in FIG. 16A. Referring to FIGS. 12 and 16A, in step S140, a preliminary protection layer P-PTL may be formed on the second preliminary base layer P-BL2. Referring also to FIG. 16B, the preliminary protection layer P-PTL may be formed to cover the second preliminary base layer P-BL2. The preliminary protection layer P-PTL may include at least one inorganic layer. For example, the inorganic layer may include silicon nitride, silicon oxynitride, and/or silicon oxide. Amorphous silicon (a-Si) may also be included.

The preliminary protection layer P-PTL may be disposed directly in contact with the second preliminary base layer P-BL2. That is, the insulating layers 10, 20, 30, 40, 50 and the conductive layers CNP1, CNP2, BML2, shown in FIG. 6, may not be disposed between the second preliminary base layer P-BL2 and the preliminary protection layer P-PTL. In an embodiment, the preliminary protection layer P-PTL may be one of the insulating layers 10, 20, 30, 40, 50.

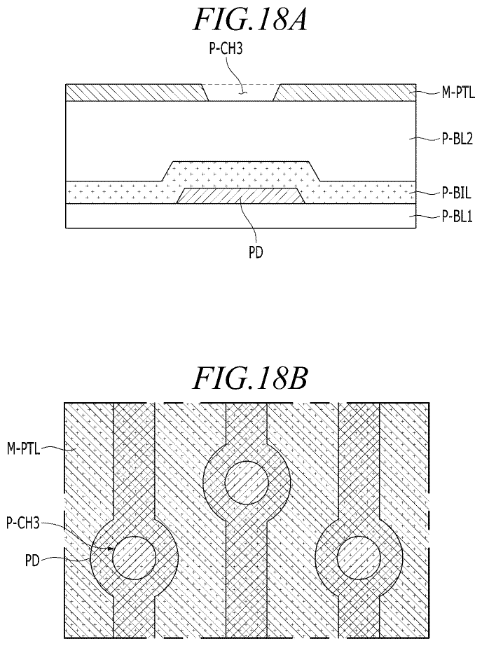

FIG. 18A is a cross-sectional view illustrating a step of the method for manufacturing a display device according to an embodiment, and FIG. 18B is a plan view illustrating a step of the method for manufacturing a display device according to an embodiment.

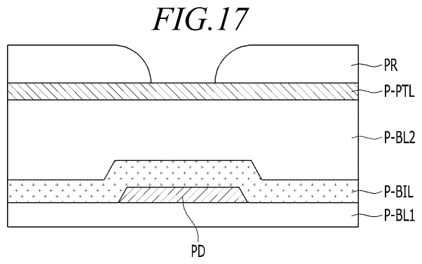

Referring to FIGS. 12, 17, and 18A, in step S150, the preliminary protection layer P-PTL may be etched to form an intermediate protection layer M-PTL. Specifically, referring to FIGS. 17 and 18A, in step S150, a photoresist layer PR may first be disposed on the preliminary protection layer P-PTL, and then the preliminary protection layer P-PTL may be etched to form the intermediate protection layer M-PTL and a third preliminary contact hole P-CH3. FIG. 18B illustrates a state in which the third preliminary contact hole P-CH3 is formed on the pad electrode PD in a planar view.

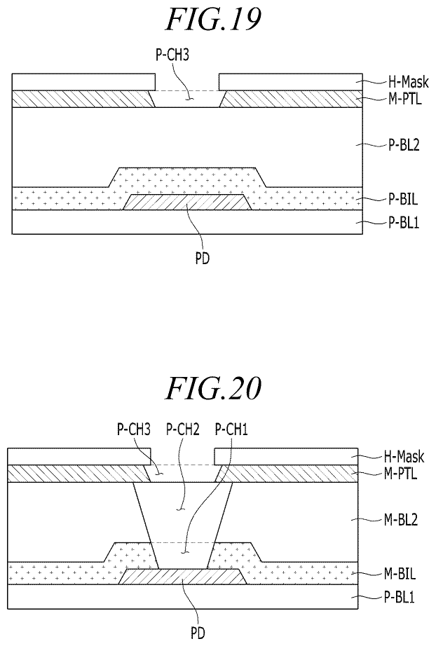

Referring to FIG. 19, in step S160, a hard mask H-Mask may be formed on the intermediate protection layer M-PTL. The hard mask H-Mask may protect the intermediate protection layer M-PTL and underlying structures during subsequent processes. The hard mask H-Mask may include a metal oxide, such as for example indium zinc oxide (IZO).

Referring to FIG. 20, in step S170, the second preliminary base layer P-BL2 and the preliminary base insulating layer P-BIL may be etched to form a second intermediate base layer M-BL2 and an intermediate base insulating layer M-BIL. During this process, a second preliminary contact hole P-CH2 may be formed in the second intermediate base layer M-BL2, and a first preliminary contact hole P-CH1 may be formed in the intermediate base insulating layer M-BIL.

In the step of etching the second preliminary base layer P-BL2, outgas that may degrade the display quality of the display device DD can be generated. However, since the intermediate protection layer M-PTL, which includes at least one inorganic layer, is formed on the second preliminary base layer P-BL2 before the etching step, the emission of outgas generated from etching the second preliminary base layer P-BL2 to the external environment may be reduced. As a result, the display quality of the display device DD may be improved.

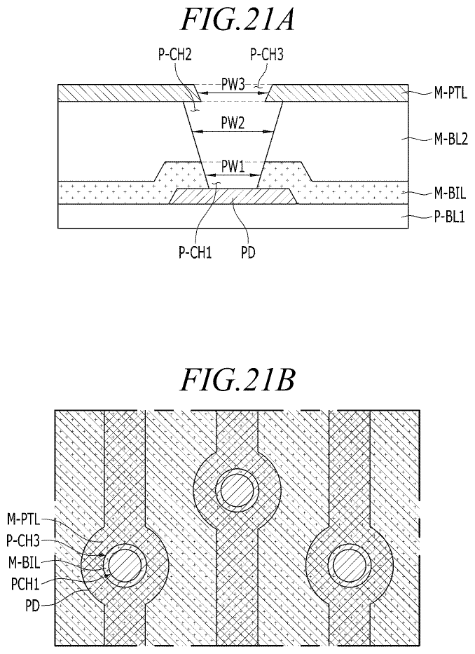

FIG. 21B illustrates the same step in a planar view. FIG. 21A is a cross-sectional view illustrating a step of the method for manufacturing a display device according to an embodiment, and FIG. 21B is a plan view illustrating the same step as shown in FIG. 21A. Referring to FIG. 21A, in step S180, the hard mask H-Mask disposed on the intermediate protection layer M-PTL may be removed. The hard mask H-Mask is removed in step S180 and, therefore, may not be included as a component of the display panel DP (shown in FIG. 2).

Referring to FIGS. 21A and 21B, a portion of the intermediate protection layer M-PTL may protrude from the edge of the second intermediate base layer M-BL2 and cover the second intermediate base layer M-BL2 in a planar view. Accordingly, as shown in FIG. 21B, the second preliminary contact hole P-CH2 may not be visible, while the first preliminary contact hole P-CH1 may be visible. However, the disclosure is not limited to this particular configuration, and in an embodiment, a portion of the intermediate protection layer M-PTL may protrude from the edge of the second intermediate base layer M-BL2 and, in a planar view, may cover both the second intermediate base layer M-BL2 and the intermediate base insulating layer M-BIL. In such a case, both the second preliminary contact hole P-CH2 and the first preliminary contact hole P-CH1 may be either completely obscured or partially visible in a planar view.

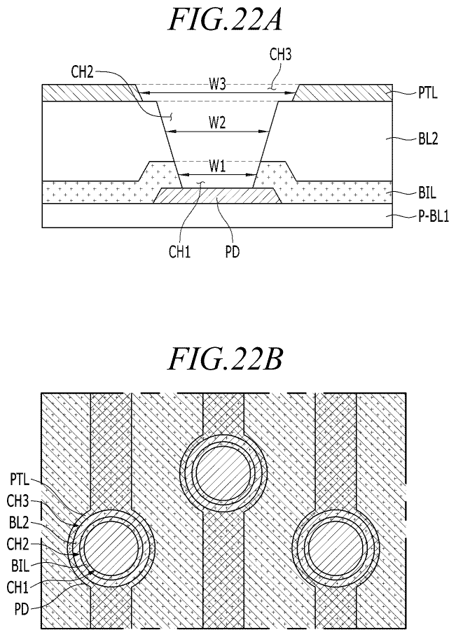

FIG. 22A is a cross-sectional view illustrating a step of the method for manufacturing a display device according to an embodiment. FIG. 22B is a plan view illustrating the same step as shown in FIG. 22A. Referring to FIGS. 21A and 22A, in step S190, the intermediate protection layer M-PTL may be etched to form the protection layer PTL, the second intermediate base layer M-BL2 may be etched to form a second base layer BL2, and the intermediate base insulating layer M-BIL may be etched to form a base insulating layer BIL. In an embodiment, the protection layer PTL, the second base layer BL2, and the base insulating layer BIL may be etched simultaneously, thereby being formed at the same time. A first contact hole CH1 may be formed in the base insulating layer BIL, a second contact hole CH2 may be formed in the second base layer BL2, and a third contact hole CH3 may be formed in the protection layer PTL.

The width W1 of the first contact hole CH1 may be greater than the width PW1 of the first preliminary contact hole P-CH1. Similarly, the width W2 of the second contact hole CH2 may be greater than the width PW2 of the second preliminary contact hole P-CH2, and the width W3 of the third contact hole CH3 may be greater than the width PW3 of the third preliminary contact hole P-CH3.

As illustrated in FIG. 22A, an interface extending from the protection layer PTL through the first to third contact holes CH1, CH2, CH3 down to the second base layer BL2, the base insulating layer BIL, and the pad electrode PD may not include an undercut and not have a step difference.

Referring to FIG. 22B, in a planar view, the protection layer PTL, the second base layer BL2, the base insulating layer BIL, and the pad electrode PD may all be visible, and the first to third contact holes CH1, CH2, CH3 may all be visible as well.

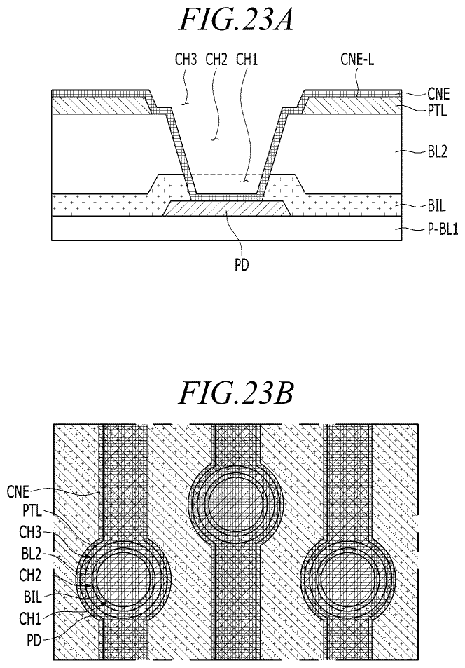

FIG. 23A is a cross-sectional view illustrating a step of the method for manufacturing a display device according to an embodiment. FIG. 23B is a plan view illustrating the same step as shown in FIG. 23A. Referring to FIG. 23A, in step S200, a connection electrode CNE may be formed on the protection layer PTL, the second base layer BL2, the base insulating layer BIL, and the pad electrode PD. The connection electrode CNE may be electrically connected to the pad electrode PD through the first to third contact holes CH1, CH2, CH3. An interface extending from the protection layer PTL through the first to third contact holes CH1, CH2, CH3 down to the second base layer BL2, the base insulating layer BIL, and the pad electrode PD may not include an undercut and not have a step difference, thereby preventing disconnection of the connection electrode CNE.

Referring to FIGS. 23A and 23B, in a planar view, the connection electrode CNE may be formed to cover the protection layer PTL, the second base layer BL2, the base insulating layer BIL, and the pad electrode PD. In an embodiment, a lower surface CNE-L of the connection electrode CNE may be in direct contact with the protection layer PTL, the second base layer BL2, the base insulating layer BIL, and the pad electrode PD.

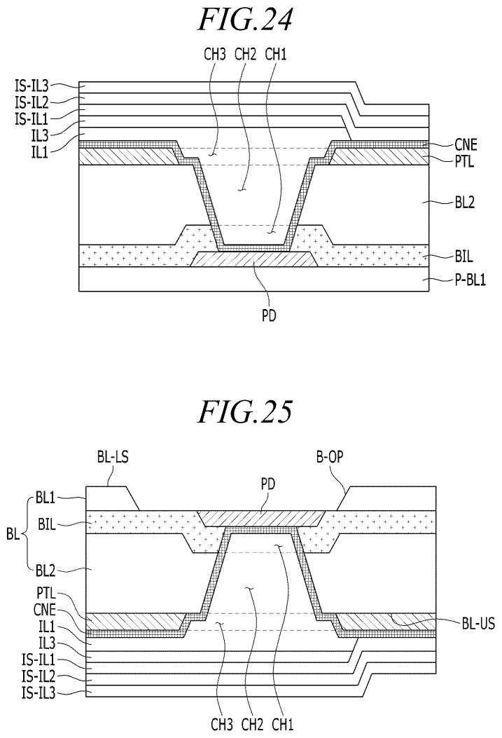

Referring to FIG. 24, the insulating layers 10, 20, 30, 40, 50 (shown in FIG. 6) and the conductive layers CNP1, CNP2, BML2 (shown in FIG. 6) may not be formed between the connection electrode CNE and the protection layer PTL. As a result, the connection electrode CNE may be disposed directly on the side surfaces of the first to third contact holes CH1, CH2, CH3 without having a step difference, thereby preventing disconnection of the connection electrode CNE due to a step difference. Additionally, connection failures between the connection electrode CNE and the pad electrode PD due to residues from the insulating layers 10, 20, 30, 40, 50 and the conductive layers CNP1, CNP2, BML2 may be prevented, thereby improving the reliability of the display device DD.

Referring to FIGS. 24 and 25, in step S210, after inverting a portion of the display device DD, the first preliminary base layer P-BL1 may be etched to form a first base layer BL1. Although not illustrated, a photoresist layer may be placed on the first preliminary base layer P-BL1, and the first preliminary base layer P-BL1 may be etched to form an opening B-OP. The pad electrode PD may be directly exposed externally through the opening B-OP formed through the first preliminary base layer P-BL1. The pad electrode PD may be exposed externally by as much as the width of the opening B-OP along the first direction DR1.

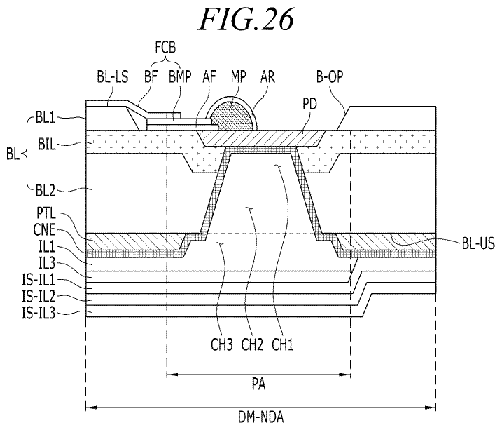

Referring to FIG. 26, in step S220, the display module DM and the circuit board FCB of the disclosure may be electrically connected to each other. Specifically, the circuit board FCB may be disposed on the first surface BL-LS of the base layer BL. An adhesive layer AF may be disposed between the circuit board FCB and the first surface BL-LS of the base layer BL. The circuit board FCB may be fixed to the first surface BL-LS of the base layer BL by the adhesive layer AF.

The circuit board FCB may include a base film BF and a bump electrode BMP disposed on the base film BF. The base film BF may be integrally formed and electrically connected to the bump electrode BMP. The bump electrode BMP may be fixed to the first surface BL-LS of the base layer BL by the adhesive layer AF. Although not illustrated, the circuit board FCB may be attached to the base layer BL in a bent state on the first surface BL-LS of the base layer BL.

In a subsequent step, a metal pattern MP may be formed. The metal pattern MP may be formed by curing metal ink. Specifically, the metal pattern MP may be formed by curing the metal ink at a low temperature and patterning the cured metal ink. The pad electrode PD and the bump electrode BMP may be electrically connected and at the same time bonded to each other via the metal pattern MP.

In a further step after the step of forming the metal pattern MP, an adhesive resin AR may be formed to cover the metal pattern MP within the opening B-OP. The adhesive resin AR may include an optical clear resin. However, the material of the adhesive resin AR is not limited thereto and may include a conventional adhesive or adhesive agent.

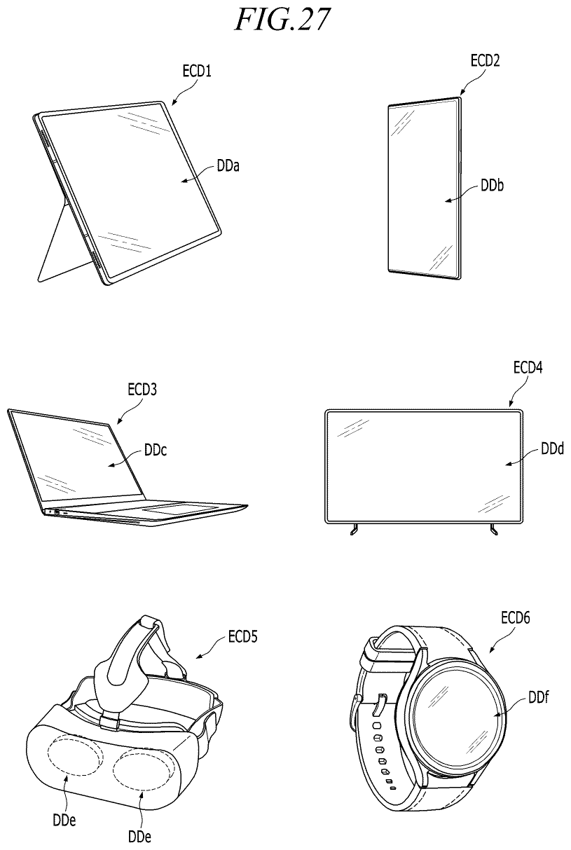

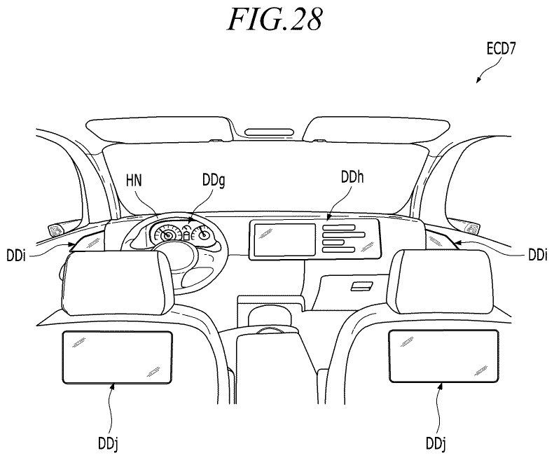

FIGS. 27 and 28 illustrate electronic devices incorporating the display device according to embodiments of the present disclosure. Referring to FIG. 27, a first electronic device ECD1 is a tablet PC including a first display device DDa. A second electronic device ECD2 is a portable terminal including a second display device DDb. A third electronic device ECD3 is a notebook computer including a third display device DDc. A fourth electronic device ECD4 is a television including a fourth display device DDd. A fifth electronic device ECD5 is a head-mounted display device including a fifth display device DDe. A sixth electronic device ECD6 is a digital watch including a sixth display device DDf.

Referring to FIG. 28, a seventh electronic device ECD7 is a vehicle including seventh to tenth display devices DDg-DDj. Although an automobile is illustrated as an example of the seventh electronic device ECD7, the present disclosure is not limited to the illustrated example and may include various types of vehicles such as, for example, a bicycle, a motorcycle, a train, a ship, and an airplane.

The seventh display device DDg may be disposed in front of a steering wheel HN in the driver's line of sight and may be used to display instrument panel information, such as the vehicle's speed. The eighth display device DDh may be disposed on the dashboard separately from the seventh display device DDg and may be used to display information relating to control interfaces, audio, temperature, road conditions, and video. The ninth display device DDi may be disposed on the sides of the driver's seat and the front passenger seat, respectively, and may function as a digital rear-view mirror. The ninth display device DDi may display images captured from the exterior of the vehicle. The tenth display device DDj may be disposed behind the driver's and passenger's seats and may be used to display images, such as videos, visible to rear-seat passengers.

In addition to the electronic devices illustrated in FIGS. 27 and 28, the display device DD according to an embodiment may be applied to electronic devices in various other fields. For example, the display device DD may be applied to various electronic devices including, but not limited to, a printer, a telephone, a wearable device, a digital camera, a camcorder, a viewfinder, a 3D display, a tiled display video wall, a theater, a signboard, a medical device, a memory, a memory processor, and a storage device.

Hitherto, certain embodiments of the present disclosure have been described above, but these are merely exemplary and are not intended to limit the present disclosure. Those skilled in the art to which the present disclosure pertains may make various modifications and changes to the embodiments by adding, changing, deleting, or adding certain elements, without departing from the scope of the technical ideas of the present disclosure as set forth in the claims, and such modifications and changes should also be regarded as being within the scope of the present disclosure.

What is claimed is:

1. A display panel comprising:
a first base layer in which an opening is defined;
a pad electrode above the opening;
a base insulating layer disposed on the first base layer and a portion of the pad electrode, wherein a first contact hole is defined in the base insulating layer;
a second base layer disposed on the base insulating layer, wherein a second contact hole above the first contact hole is defined in the second base layer;
a protection layer disposed on the second base layer, wherein a third contact hole above the first contact hole and the second contact hole is defined in the protection layer; and
a connection electrode disposed on the protection layer and electrically connected to the pad electrode through the first contact hole, the second contact hole, and the third contact hole,
wherein a width of the third contact hole is greater than a width of the second contact hole.

2. The display panel of claim 1, wherein the width of the second contact hole is greater than a width of the first contact hole.

3. The display panel of claim 1, wherein the pad electrode extends parallel to a plane defined by a first direction and a second direction intersecting the first direction.

4. The display panel of claim 1, wherein the pad electrode comprises:
a first portion directly contacting the connection electrode; and
a second portion not contacting the connection electrode, wherein the first portion is below the first contact hole in a planar view.

5. The display panel of claim 4, wherein the second portion is disposed below the base insulating layer, and
wherein an upper surface of the second portion is in direct contact with the base insulating layer.

6. The display panel of claim 4, wherein the base insulating layer is in direct contact with a side surface of the second portion.

7. The display panel of claim 4, wherein the base insulating layer covers the second portion.

8. The display panel of claim 1, wherein a lower surface of the connection electrode is in direct contact with the protection layer, the second base layer, the base insulating layer, and the pad electrode.

9. The display panel of claim 1, wherein the base insulating layer comprises:
an amorphous silicon layer; and
a silicon oxide layer disposed on the amorphous silicon layer,
wherein the silicon oxide layer has a thickness of at least 100 Å.

10. The display panel of claim 1, wherein the base insulating layer comprises at least one of silicon oxide (SiOx), silicon nitride (SiNx), or silicon oxynitride (SiON).

11. The display panel of claim 1, wherein the second base layer comprises an organic material.

12. The display panel of claim 1, wherein the protection layer comprises at least one inorganic layer.

13. The display panel of claim 1, wherein a thickness of the second base layer is greater than a thickness of the protection layer.

14. The display panel of claim 1, wherein the first base layer comprises a display area and a non-display area, and
wherein the pad electrode overlaps the non-display area.

15. A method for manufacturing a display panel, comprising:
forming a pad electrode on a first preliminary base layer;
forming a preliminary base insulating layer on the first preliminary base layer and a portion of the pad electrode;
forming a second preliminary base layer on the preliminary base insulating layer;
forming a preliminary protection layer on the second preliminary base layer;
etching the preliminary protection layer to form an intermediate protection layer, wherein a third preliminary contact hole is defined in the intermediate protection layer;
etching the second preliminary base layer and the preliminary base insulating layer to form a second intermediate base layer and an intermediate base insulating layer, wherein a second preliminary contact hole is defined in the second intermediate base layer, and a first preliminary contact hole is defined in the intermediate base insulating layer;
etching the intermediate protection layer, the second intermediate base layer, and the intermediate base insulating layer to form a protection layer, a second base layer, and a base insulating layer, wherein a first contact hole is defined in the protection layer, a second contact hole is defined in the second base layer, and a third contact hole is defined in the base insulating layer, the first contact hole being below the second contact hole, and the second contact hole being below the third contact hole in a planar view; and
forming a connection electrode on the portion of the pad electrode, the protection layer, the second base layer, and the base insulating layer,
wherein the connection electrode is electrically connected to the pad electrode through the first contact hole, the second contact hole, and the third contact hole, and
wherein the third contact hole has a width greater than a width of the second contact hole.

16. The method of claim 15, further comprising forming a hard mask on the intermediate protection layer, and before forming the second intermediate base layer and the intermediate base insulating layer.

17. The method of claim 16, further comprising removing the hard mask, after forming the second intermediate base layer and the intermediate base insulating layer, and before forming the protection layer, the second base layer, and the base insulating layer.

18. An electronic device comprising:
a housing;
an electronic module disposed inside the housing; and
a display device disposed to overlap with the electronic module,
wherein the display device comprises:
a display panel configured to display an image; and
a circuit board coupled to the display panel,
wherein the display panel comprises:
a first base layer in which an opening is defined;
a pad electrode above the opening;
a base insulating layer disposed on the first base layer and a portion of the pad electrode, wherein a first contact hole is defined in the base insulating layer;
a second base layer disposed on the base insulating layer, wherein a second contact hole above the first contact hole is defined in the second base layer;
a protection layer disposed on the second base layer, wherein a third contact hole above the first contact hole and the second contact hole is defined in the protection layer; and
a connection electrode disposed on the protection layer and electrically connected to the pad electrode through the first contact hole, the second contact hole, and the third contact hole,
wherein a width of the third contact hole is greater than a width of the second contact hole.

19. The electronic device of claim 18, further comprising a metal pattern electrically connecting the display panel and the circuit board.

20. The electronic device of claim 19, wherein the circuit board comprises:
a base film; and
a bump electrode disposed between the base film and the base insulating layer,
wherein the bump electrode and the pad electrode are electrically connected through the metal pattern.
